(19) United States
(12) Patent Application Publication
(10) Pub. No.: US 2012/0182014 A1
(43) Pub. Date: Jul. 19, 2012

(54) MAGNETIC RESONANCE MICROCOIL AND METHOD OF USE

(76) Inventors: Debra Strick Rivera, Santa Monica, CA (US); Jack W. Judy, Vienna, VA (US); Mark S. Cohen, Calabasas, CA (US); Dixie J. Mills, Cambridge, MA (US)

(21) Appl. No.: 13/390,035

(22) PCT Filed: Aug. 11, 2010
(86) PCT No.: PCT/US10/45219

§ 371 Date: Apr. 6, 2012

Related U.S. Application Data
(60) Provisional application No. 61/233,337, filed on Aug. 12, 2009.
(60) Provisional application No. 61/233,349, filed on Aug. 12, 2009.

(51) Int. Cl. G01R 33/44

(52) U.S. Cl. 324/318

(57) ABSTRACT

A magnetic resonance imaging device includes an elongate flexible member having a proximal end, a distal end, and a lumen extending between the proximal end and the distal end and a solenoid coil affixed to the distal end of the elongate flexible member, the solenoid coil having a plurality of wire turns, the solenoid coil connected to a twisted-pair of leads extending proximally along the length of the flexible member. A connector is disposed at the proximal end of the elongate flexible member, the connector operatively coupled to the twisted-pair of leads. In an alternative embodiment, a coaxial cable substitutes for the lumen-containing elongate flexible member.

### REFERENCE TO RELATED APPLICATIONS

This Application claims priority to U.S. Provisional Patent Application No. 61/233,337, filed on Aug. 12, 2009 and U.S. Provisional Patent Application No. 61/233,349, filed on Aug. 12, 2009. The above-noted U.S. patent applications are incorporated by reference as if set forth fully herein.

### FEDERALLY-SPONSORED RESEARCH AND DEVELOPMENT

This invention was made with Government support of National Science Foundation—Integrative Graduate Education and Research Traineeship (IGERT) Fellowship #9972802. The Government has certain rights in this invention.

### FIELD OF THE INVENTION

The field of the invention generally relates magnetic resonance coils and in particular, magnetic resonance imaging coils that are implantable within a mammalian body.

### BACKGROUND

Magnetic Resonance (MR) coils receive small signals from proton populations. The proton populations create a small alternating magnetic field that induces an alternating current in a properly positioned and tuned Magnetic Resonant Imaging (MRI) coil. By placing the MRI coil inside of a subject, this increases the proximity of the coil to the signal-emitting tissue, thereby increasing the strength of the signal. A small coil placed inside the patient generally only receives signals from neighboring tissue. Because of this, un-wanted signals from protons outside the localized region of interest are reduced.

The increase in signal-to-noise-ratio (SNR) provided by implanting MRI coils has been established by others in the field. For instance, Kantor et al. achieved success in increasing the SNR with an implantable MRI coil that imaged phosphorous nuclei in the canine heart. See H. L. Kantor et al., “In vivo 31P nuclear magnetic resonance measurements in canine heart using a catheter-coil,” Circulation Research, Vol. 55, pp. 261-266 (1984). Others used implantable coils for both MR imaging and MR spectroscopy of in vivo blood vessels. For example, Atalar et al. obtained 100 μm in-plane resolution images, averaged from 3 mm thick proton populations (slice thicknesses) of the rabbit aorta in vivo. See E. Atalar et al., “High resolution intravascular MRI and MRS by using a catheter receiver coil.” Magnetic Resonance in Medicine, Vol. 36, pp. 596-605 (1996).

Most catheter coils, however, use a single-loop configuration which is optimized for imaging larger diameter blood vessels (e.g., >3 mm) oriented along the antero-posterior axis. Unfortunately, this approach sacrifices SNR to cover a long region of the vessel wall. In many applications, there is a need for small spatial resolution with high signal-to-noise ratio (SNR) around a tissue region of interest. The single-loop design is not suited for this particular application. Additional modalities have been developed to achieve high SNR on a small scale (i.e., single cell) using NMR microcoils. See S. Grant et al., “NMR Spectroscopy of Single Neurons.” Magnetic Resonance in Medicine, Vol. 44, pp. 19-22 (2000), and for a review see A. Webb, “Radiofrequency microcoils in magnetic resonance” Progress in Nuclear Magnetic Resonance Spectroscopy, Vol. 31, pp. 1-42 (1997). NMR microcoils are small solenoids that range in diameter from 350 μm to 2 mm and provide increased sensitivity. These NMR microcoils are typically wound around glass capillaries mounted on silicon chips and therefore cannot be implemented in vivo.

There thus is a need for a small microcoil that can be used, in vivo, to target small tissue samples for enhanced MR signal reception. Such a device could be used in a variety of research, diagnosis, and treatment planning applications for diseases such as cancer and epilepsy.

### SUMMARY

In one embodiment, a magnetic resonance imaging device includes an elongate flexible member having a proximal end, a distal end, and a lumen extending between the proximal end and the distal end. A solenoid coil is affixed to the distal end of the elongated flexible member, the solenoid coil having a plurality of wire turns, the solenoid coil connected to a twisted-pair of leads extending proximally along the length of the flexible member. The device includes a connector disposed at the proximal end of the elongate flexible member, the connector operatively coupled to the twisted-pair of leads.

In another embodiment, a method of using the magnetic resonance imaging device includes placing a subject within a static magnetic field and inserting the elongate flexible member into a tissue region of interest. The magnetic resonance imaging device includes a solenoid coil that is generally oriented orthogonal to the static magnetic field. The solenoid coil may be operated as a receive-only coil or, alternatively, the solenoid coil may be operated as a transceiver. In the transceiver mode, a duplexer is needed to switch between transmit and receive modes. The magnetic resonance imaging device may be a stand-alone device or it may be integrated with another device such as, for instance, an imaging device (i.e., endoscope), depth electrode, or other device.

In yet another embodiment, a method of making a magnetic resonance imaging coil includes wrapping an insulated conductor around a tubular elongate member for a plurality of turns to form a solenoid coil. A twisted-pair of leads from a portion of the insulated conductor is formed and the twisted-pair of leads is then secured relative to the tubular elongate member. An optional stylet may be inserted into the tubular elongate member prior to forming the turns of the solenoid coil. The stylet may be removed after forming the coils, and reinserted to facilitate implantation. Alternatively, a coaxial cable can be used in place of the twisted-pairs either with or without the tubular elongate member. In such an embodiment, the main axis of the microcoil can either be parallel to or orthogonal to the coaxial cable. Such a device would be ideal for use inside the working channel of an interventional device such as an endoscope.

Further features and advantages will become apparent upon review of the following drawings and description.

### BRIEF DESCRIPTION OF THE DRAWINGS

FIG. 1A is a side view of a magnetic imaging device according to one embodiment.

FIG. 1B is a cross-sectional view of the magnetic imaging device of FIG. 1A taken along the line A-A′.

FIG. 1C is a cross-sectional view of adjacent windings of a solenoid coil according to one embodiment exhibiting 3R spacing of adjacent centers.

FIG. 1D is a perspective view of a solenoid coil according to one embodiment.

FIG. 1E is a photographic image of a solenoid coil wrapped around a silicone elongate member according to another embodiment.

FIG. 1F is an electrical schematic of a parallel tank circuit with series matching capacitor that may be used to tune the solenoid coil according to one embodiment.

FIG. 2 is a schematic representation of a system that includes a static magnetic field along with a magnetic imaging device operating as a transceiver according to one embodiment.

FIG. 3 is an electrical schematic of a magnetic imaging device operating as a transceiver according to one embodiment.

FIG. 4 illustrates the proton spectrum of mayonnaise using a standard Head Coil and the inventive solenoid coil. Distinctive fat and water components (peaks) are illustrated.

FIGS. 5A and 5B illustrate images obtained of ex vivo neural tissue (butcher grade neural tissue—Ovis aries) with a solenoid coil having a 1 mm diameter.

FIG. 6A illustrates a side view of a magnetic imaging device according to another embodiment.

FIG. 6B illustrates a cross-sectional view of the magnetic imaging device of FIG. 6A taken along the line B-B′.

FIG. 7A illustrates a cross-sectional view of an endoscope with a working channel configured to accommodate a microcoil.

FIG. 7B illustrates a side view of one embodiment of a magnetic imaging device having a microcoil mounted on the distal end of a coaxial cable. The microcoil is illustrated as being substantially parallel to the long axis of the coaxial cable.

FIG. 7C illustrates a side view of one embodiment of a magnetic imaging device having a microcoil mounted on the distal end of a coaxial cable. The microcoil is illustrated as being substantially perpendicular to the long axis of the coaxial cable.

### DETAILED DESCRIPTION OF ILLUSTRATED EMBODIMENTS

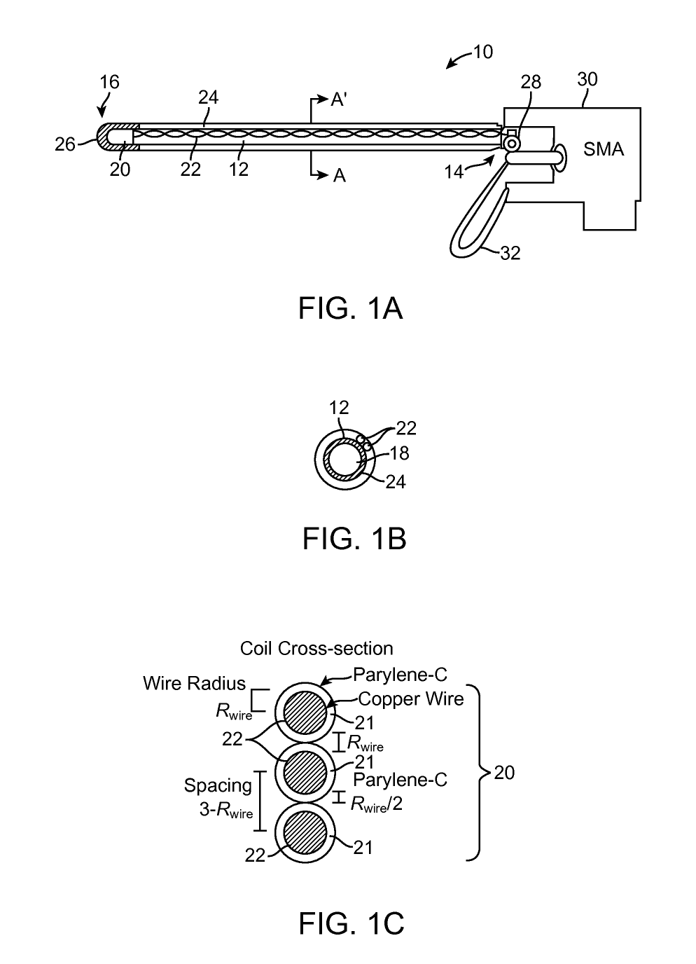

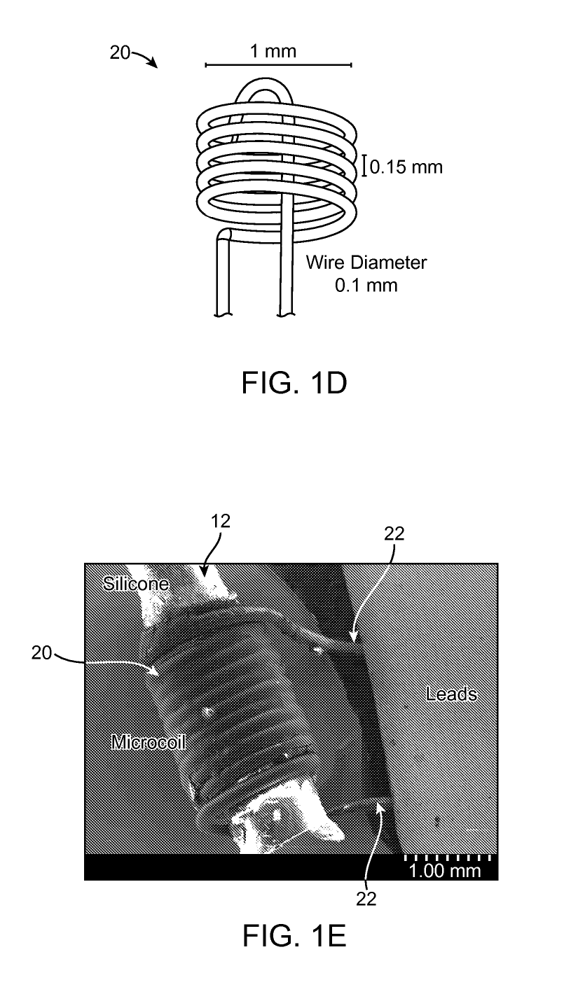

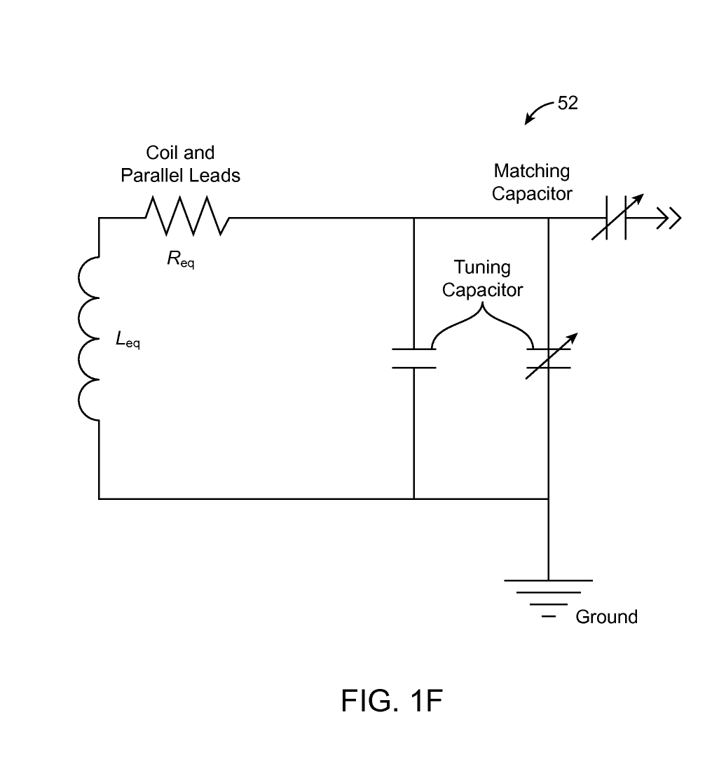

FIG. 1A is a schematic representation of a magnetic imaging device 10 according to one embodiment of the invention. The device includes an elongate flexible member 12 that has a proximal end 14, a distal end 16, and a lumen 18 extending from the proximal end 14 to the distal end 16 as best seen in FIG. 1B. The elongate flexible member 12 in one aspect of the invention may include silicone tubing. An example of silicone tubing that may be used includes, for example, tubing having an inner diameter of around 0.51 mm, an outer diameter of around 0.94 mm, a wall thickness of around 0.22 mm. Such tubing may include biomedical grade silicone tubing such as catalog number 806400 available from A-M System, Inc. of Squim, Wash. Of course, other dimensions of tubing may also be contemplated. For instance, the elongate flexible member 12 may be formed as a catheter device that is formed from a biocompatible polymer material. The stiffness of the elongate flexible member 12 may vary along its length. For example, stiffness may increase as one moves proximally toward the proximal end 14. Further, the stiffness may vary depending on the application in which the magnetic imaging device 10 may be used. Alternatively, the stiffness may be substantially uniform along the length of the elongate flexible member 12.

Still referring to FIG. 1A, the magnetic imaging device 10 includes a solenoid coil 20 disposed at the distal end of the elongate flexible member 12. The solenoid coil 20 is made of an electrical conductor such as a wire. For example, copper wire may be used that is coated with an insulator. One example of wire that may be used for the solenoid coil 20 includes 38 gauge copper wire (available from Belden, St. Louis, Mo., catalog number 8058). The wire may also be made of other conductors such as gold or silver wire. The copper wire may be bare or coated with an insulator such as a polytetrafluoroethylene (PTFE) coating. The solenoid coil 20 is preferably formed with at least three complete coil turns. Adjacent coils of the solenoid coil 20 are spaced apart from one another by an insulator coating 21 (as seen in FIG. 1C) placed on the copper wire. By adjusting the thickness of the coating, this will adjust the spacing between adjacent coils. In one aspect of the invention, the centers of adjacent turns of the wire are separated by 3 wire radii to maximize inductance while minimizing resistance. FIG. 1C illustrates the 3 wire radii separating between adjacent windings of the solenoid coil 20. Parylene C is illustrated as the insulator coating 21.

For example, Parylene C of a controlled thickness may be coated onto the copper wire using a vacuum deposition process such as that employed by the 2010 LABCOATER2, available from Specialty Coating Systems, Inc., Indianapolis, Ind. In this process copper wire is strung on a metal frame before placing the same inside the vacuum chamber. For a 100 μm diameter wire, a layer of 25 μm Parylene C was deposited on the wire for a final diameter of approximately 150 μm. To form the solenoid coil 20 about the elongate flexible member 12, a stylet (not shown) may be optionally inserted into the elongate flexible member 12 prior to wrapping of the coil to avoid deformation during subsequent steps. The wire with the Parylene C coating is wrapped around the distal end of the elongate flexible member 12 such that adjacent turns in the coil are placed in contact such that the wire insulation defined the turn spacing. The number of turns of the coil for a particular solenoid coil 20 may vary but generally includes at least three (3) complete turns. In other embodiments, more turns may be used. For example, a solenoid coil 20 having ten turns with a 1 mm diameter may be used. Of course, the solenoid coil 20 may have a different number of turns or even partial turns with various diameters. Generally, the benefits of the solenoid coil 20 design are best obtained with coil diameters of less than 2 mm. For example, a range of coil diameters may be used between about 200 μm to about 2 mm.

The turns of the solenoid coil 20 may be secured to the underlying elongate flexible member 12 using an adhesive or the like. For example, cyanoacrylate adhesive (HS-2, Satellite City Hot Stuff, Simi, Calif.) may be used to secure the turns of the solenoid coil 20 to the elongate flexible member 12.

FIG. 1D illustrates one embodiment of a solenoid coil 20 that includes solenoid coil 20 having three turns with a diameter of 1 mm and a wire diameter of 0.1 mm. FIG. 1D illustrates one conductor passing through the center region of the coil. In other embodiments, this central conductor may be omitted. FIG. 1E illustrates another embodiment of a solenoid coil 20 that includes 10 turns. This last solenoid coil 20 was designed for a MR field of 3 T at 123 MHz and had a diameter of 1 mm. The solenoid coil 20 had a reactance (wL) of 50Ω. By having the solenoid coil 20 disposed at the distal end 16 of the elongate flexible member 12 and crowded together, the probe is forward directing.

Referring back to FIG. 1A, the free end of the wire forming the solenoid coil 20 is formed into a twisted pair of leads 22. The twisted pair of leads 22 may be formed by securing the free ends of the wire together and twisting the free ends relative to the solenoid coil 20. Tape may be used to secure the twisted pair of leads 22 together. The taped leads 22 can then be mounted in a pin vise which is then rolled to achieve a uniform twisted pair 22. Generally, there may be around 1 twist per mm. The twisted pair of leads 22 extends proximally along the length of the elongate flexible member 12. The length of the twisted pair of leads 22 may vary but generally is several centimeters or longer (e.g., 5 cm long segment).

In one embodiment, the twisted pair of leads 22 are interposed or sandwiched (in a concentric arrangement) between elongate flexible member 12 and an outer tubular member or jacket 24 as seen in FIGS. 1A and 1B. The outer tubular member 24 may include heat-shrink tubing, the like, or a conformal coating. This outer tubular member 24 covers the solenoid coil 20. For example, the outer tubular member 24 may be formed or trimmed to be within around 0.1 mm of the distal end 16. In order to prevent moisture from wicking between the concentric elongated members 12 and 24, it is sometimes necessary to seal the layers with an additional coating such as polydimethylsiloxane (PDMS).

Still referring to FIG. 1A, the magnetic imaging device 10 includes a connector 30 connected to the proximal end 14 of the elongate flexible member 12. The connector 30 may include a coaxial RF connector such as a SubMiniature Version A (SMA) connector. SMA connectors may be obtained from a variety of manufacturers including Radiall of Paris, France. As seen in FIG. 1A, one lead of the twisted pair of leads 22 is coupled to the outer conductor of the SMA connector 30. The other lead of the twisted pair of leads 22 is connected to a series tuning capacitor 28 (9402-6 Johanson Manufacturing, USA) which, in turn, coupled to the center conductor of the SMA connector 30. Parallel-inductance matching is provided by a looped brass foil 32 (18 pF) connecting between the center and outer conductors of the SMA connector 30. In this regard, tuning and matching circuitry is integrated into the connector 30. The configuration illustrated in FIG. 1A reduces the interdependence of tuning and matching.

The solenoid coil 20 can be tuned and matched in other ways including the use of parallel and series capacitors to match the resistance to the characteristic impedance of the system (i.e. cables, connectors, and transmitter) and tune the solenoid coil 20 to the operating frequency. By characterizing the complex impedance of the solenoid coil 20 with a network analyzer, or a signal generator and oscilloscope, approximate values for the capacitors can be determined. For example, a parallel tank circuit with series matching capacitor as illustrated in FIG. 1F may be used to tune the solenoid coil 20. While a circuit like the one of FIG. 1F may be used for tuning, the tuning and matching features of FIG. 1A reduced the interdependence of tuning and matching. The tuning and matching can occur near the solenoid coil 20, outside of the region that is inside the body, or a combination of the two.

During use, the magnetic imaging device 10 may be inserted into a tissue region of interest using an introducer sheath or trocar (not shown) known to those skilled in the art. The length of the magnetic imaging device 10 may be such that the solenoid coil 20 extends beyond the distal length of any introducer sheath or trocar. The magnetic imaging device 10 may also include an optional guide or the like such that the same can be guided over a guide wire or the like. Alternatively, the magnetic imaging device 10 may be inserted into the tissue directly without the aid of any introducer sheath or trocar.

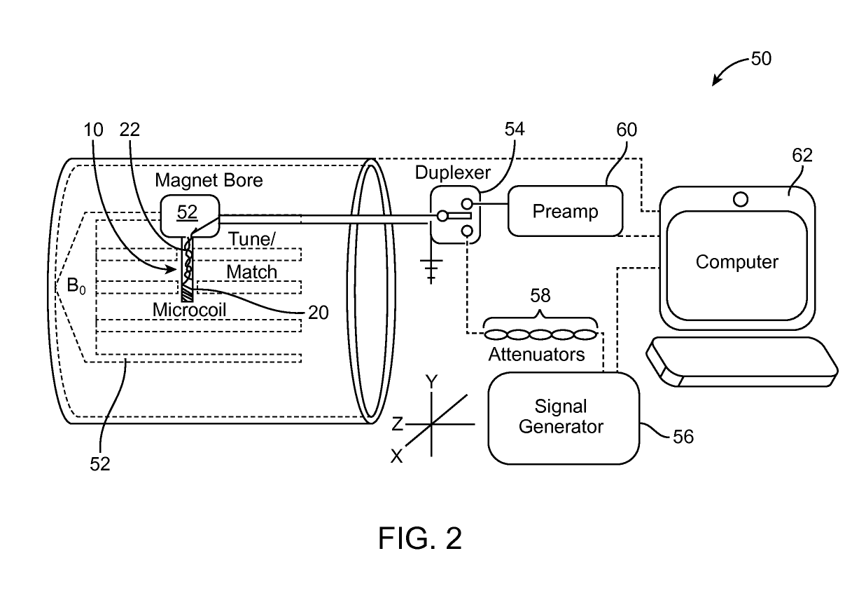

FIG. 2 illustrates a system 50 that includes the magnetic imaging device 10. The system includes a static magnetic field source 52 which may take the configuration of a conventional MRI instrument. As seen in FIG. 2, the magnetic imaging device 10 is located inside the magnet bore of a MRI instrument which is the static magnetic field source 52. The magnetic imaging device 10 is oriented generally perpendicular to the main magnetic field. MR signal reception is best achieved by placing the solenoid coil 20 orthogonal to the large static magnetic field. By having the solenoid coil 20 and the magnetic imaging device 10 oriented generally perpendicular to the body, the twisted pair of leads 22 can be relatively short, thereby minimizing signal attenuation and MR heating.

As seen in FIG. 2, the magnetic imaging device 10 includes tuning and matching circuitry 52. This is located in the bore of the MRI instrument as seen in FIG. 2 but this may be located elsewhere.

Still referring to FIG. 2, the magnetic imaging device 10 is illustrated as a transceiver. That is to say, the magnetic imaging device 10 both transmits and receives signals. Because the device transmits and receives, a duplexer 54 is illustrated which enables the system to switch between transmit and receive modes. On the transmit side of the system 50, a signal generator 56 is connected to the duplexer 54 via an attenuator 58. The attenuator 58 may comprise a series of attenuators that are combined for additional total attenuation as illustrated in FIG. 2 or the attenuator 58 may comprise a single attenuator. Attenuation of around 20-25 dB may be typical although other values may be employed. On the receive side of the system 50, the receive signal flows from the solenoid coil 20, through the duplexer 54 and into a preamplifier 60 for signal amplification. As seen in FIG. 2, a computer 62 may be incorporated into the system 50 to receive signals from the preamplifier for storage and processing. In addition, the computer 62 may also be operatively connected to control the signal generator 56 as well as the static magnetic field source 52.

While FIG. 2 illustrates a system 50 for transmission and receiving, the magnetic imaging device 10 could be used just as a receive-only coil. In this mode, one can use a crossed-diode scheme or a PIN diode (with or without a detuned inductor) as known to those skilled in the art to detune the solenoid coil 20 and prevent coupling of the transmit power to the receive coil.

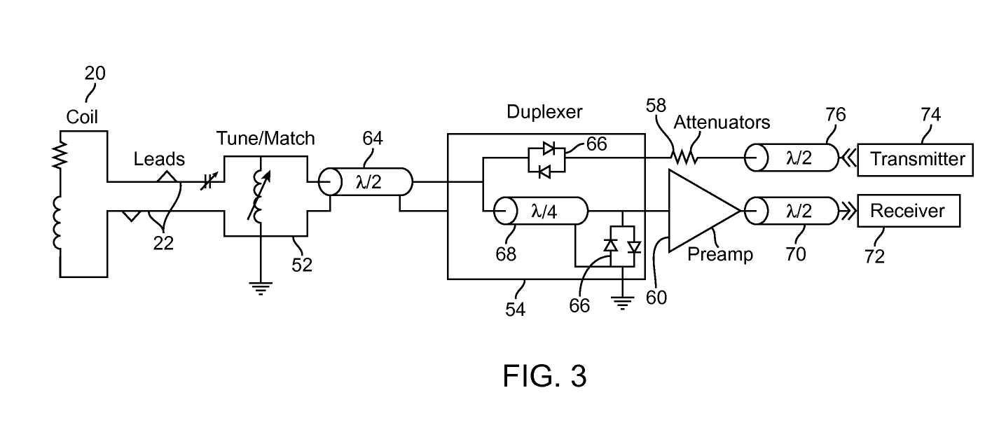

FIG. 3 illustrates an electrical schematic diagram of one embodiment of circuitry used with the magnetic imaging device 10 in a transceiver mode. As seen in FIG. 3, the solenoid coil 20 terminates in a twisted pair of leads 22 that lead to tuning and matching circuitry 52. The tuning and matching circuitry 52 is coupled to a half wave coaxial cable 64 which, in turn, connects to duplexer 54. The duplexer 54 illustrated in FIG. 3 has two pairs of anti-parallel Schottky diodes 66 (Part No. 5082-2810, Agilent Technologies, USA) with a quarter wave transformer 68. Alternatively, the anti-parallel Schottky diodes 66 can be replaced with a PIN diode. On the receive side of the duplexer 54, the receive signal is run through a preamplifier 60 (123GNST, Angle Linear, Lomita, USA) and then through a half wave coaxial cable 70 before passing to receiver 72. On the transmit side of the duplexer 54, a transmitter 74 which typically includes a signal generator that passes through a half wave coaxial cable 76 before passing through an attenuator 58 (20 dB attenuator, RFS30G04/20 dB, RF Lambda, Plano, Tex., USA). The attenuated signal then passes to the duplexer 54. Of course, it should be understood that the transmitter 74 and receiver 72 may be integrated into a single device such as an MR scanner or even a computer 62 as illustrated in FIG. 2.

A particular benefit of the magnetic imaging device 10 described herein is the ability to leverage the high sensitivity and specificity of imaging device to identify sub-millimeter features. For example, the magnetic imaging device 10 could be employed to detect early-stage breast cancer. In breast cancer, more than 95% of breast cancers originate in the mammary ducts. See S. Murata et al, “Ductal Access for Prevention and Therapy of Mammary Tumors.” Cancer Research, Vol. 66, pp. 638-45 (2006). However, clinicians cannot reliably diagnose cancers at this early intraductal stage. Magnetic Resonance Spectroscopy (MRS) can distinguish between benign and malignant tissue with specificity and sensitivity up to 80%. See R. Katz-Brull et al, “Clinical Utility of Proton Magnetic Resonance Spectroscopy in Characterizing Breast Lesions.” Journal of National Cancer Institute, Vol. 94, pp. 1197-1203 (2002). Unfortunately, conventional MRS methods are limited to late-stage diagnosis because a large amount (e.g., ˜cm³ sized) malignant tissue is needed. See S. Sinha et al, “Recent advances in breast MRI and MRS.” NMR in Biomedicine, Vol. 22, pp. 3-16 (2009). Other conventional approaches for identifying ductal carcinomas during the in situ phase suffer from poor sensitivity (dynamic contrast enhanced (DCE)-MRI: 40-89%; mammography: 37-55%; ultrasound: 47%). See I. Obdeijn et al, “Assessment of false-negative cases of breast MR imaging in women with a familial or genetic predisposition.” Breast Cancer Research and Treatment, Vol. 119, pp. 399-407 (2010), and F. Sardanelli et al, “Sensitivity of MRI Versus Mammography for Detecting Foci of Multifocal, Multicentric Breast Cancer in Fatty and Dense Breasts Using the Whole-Breast Pathologic Examination as a Gold Standard” American Journal of Roentgenology, Vol. 183, pp. 1149-1157 (2004).

Direct imaging of the ducts is possible through mammary ductoscopy, however, ductoscopic cytology is insufficient for diagnosing malignancies. See W. Sarakbi et al, “Does mammary ductoscopy have a role in clinical practice?”, International Seminars in Surgical Oncology, Vol. 3, 16 (2006). In contrast, the magnetic imaging device 10 provides a small-sized solenoid coil 20 on the order of 1 mm in diameter that can be directly inserted into the mammary ducts to image breast tissue for malignancies. The solenoid coil 20 can be used at any field strength and with reduced diameters suitable for in situ imaging of ductal tissue. It may be combined with ductoscopy to enhance sensitivity, or with DCE-MRI to confirm whether there is a true or false positive.

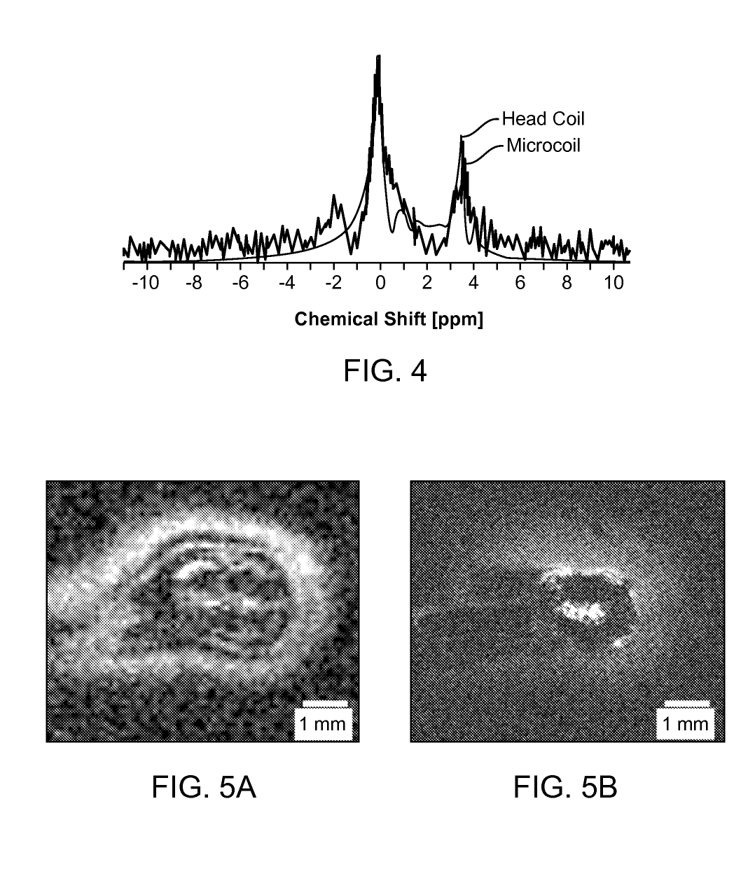

FIG. 4 illustrates how the solenoid coil 20 is capable of providing microliter spectroscopy. In particular, FIG. 4 illustrates spectra (3-T TIM Trio scanner, Siemens AG, Germany) obtained from a 1.5 μL sample of mayonnaise taken with a magnetic imaging device 10 having a 1 mm diameter solenoid coil 20 (STEAM; 10 Hz; 25 V). Also illustrated for comparison purposes is the spectra obtained from a larger 7.5 mL sample of mayonnaise taken with a matrix-head coil (STEAM; 10 Hz: 300 V). Both spectra, taken from a single free induction decay, illustrate the distinct peaks of the water and fat components. The microcoil sample and 5000× fewer spins.

The magnetic imaging device 10 may also be used to image other tissue types besides breast tissue. For instance, neural tissue may be imaged using the magnetic imaging device 10. FIGS. 5A and 5B illustrate images obtained of ex vivo neural tissue (butcher grade neural tissue—Ovis aries) with a solenoid coil 20 having a 1 mm diameter with ten turns. The solenoid coil 20 was positioned orthogonally within a static field of a 3 T/123 MHz MRI scanner. Transverse scout images were obtained using a gradient-recalled-echo (GRE) pulse sequence. Transverse images were obtained with the following turbo spin-echo imaging sequence: 256×256 image matrix; 0.10 mm in-plane resolution; 0.4 mm slice thickness; TR/TE of 3000 22 ms; 7 echoes with 21.6 ms spacing; an acquisition time of 0:05:29 (hr:min:s); 3 averaged; 15 slices; fat saturation; and bandwidth of 130 Hz/pixel. As well with the following GRE sequence: 1024×1024 image matrix; 0.021 mm in-plane resolution; 0.17 mm slice thickness; TR/TE of 123/48 ms; an acquisition time of 3:56:10; 6 averages; 1 slab with 30 slices; fat saturation; and a bandwidth of 19 Hz/pixel. FIG. 5A illustrates 100 μm in-plane resolution with 400 μm-thick slices. FIG. 5B illustrates 20 μm in-plane resolution with 170 μm-thick slices.

The magnetic imaging device 10 may also be used in conjunction with the use of intracranial electrodes for the treatment of temporal-lobe epilepsy (TLE). The magnetic imaging device 10 having a solenoid coil 20 can be used for both imaging and spectroscopy. In addition to aiding in research, diagnosis, and treatment planning for TLE, the magnetic imaging device 10 can also be used for other neurological disorders such as Parkinson's Disease.

The magnetic imaging device 10 may be a separate device used alongside an intracranial electrode. Alternatively, the magnetic imaging device 10 could be integrated into a single device having both electrodes as well as a solenoid coil 20 for imaging and spectral analysis functionality. In this regard, a single device could provide spatially correlated electrophysiology data with high-SNR images and chemical analysis. Materials with magnetic susceptibility matched to the tissue can minimize MRI artifacts. Materials with magnetic susceptibility similar to tissue include gold and copper. The increased SNR will increase the ability of clinicians to locate lesions, thereby increasing the success rate of, and number of candidates for, surgical treatment of TLE. Microanatomy and chemical composition of seizure-inducing tissue can be done in vivo. Combined localization of epileptogenic and ictal waveforms with microanatomy MRI may elucidate underlying morphology of different classes. For example, identifying morphological and metabolic changes associated with waveforms known as “fast ripples” in humans may lead to new anti-epileptic drug treatments and new markers for seizure generating tissue. Thus far, such waveforms have been difficult to identify in living tissue as the affected region is thought to be on the order of a cubic millimeter. See A. Bragin et al, “Local Generation of Fast Ripples in Epileptic Brain” Journal of Neuroscience, Vol. 22, pp. 2012-2021 (2002).

The magnetic imaging device 10 may also be used in refined metabolic studies. While MRS can quantify metabolic changes in epilepsy, the spatial resolution is very coarse. Intracranial solenoid coils 20 placed throughout the temporal lobe can obtain spectroscopic data from regions on the order of a cubic millimeter, thus alleviating the problem associated with MRS of an inability to isolate individual neural structures such as the hippocampus and amygdala. This would permit an investigation into the metabolic changes in isolated neural structures (e.g., hippocampus, entorhinal cortex, and amygdala), and substructures (e.g., hippocampus regions CA1 and CA3). Other adaptations of the solenoid coils 20 include the study and identification of lesions, tumors, and microanatomy of tissue which are associated with diseases such as cancer.

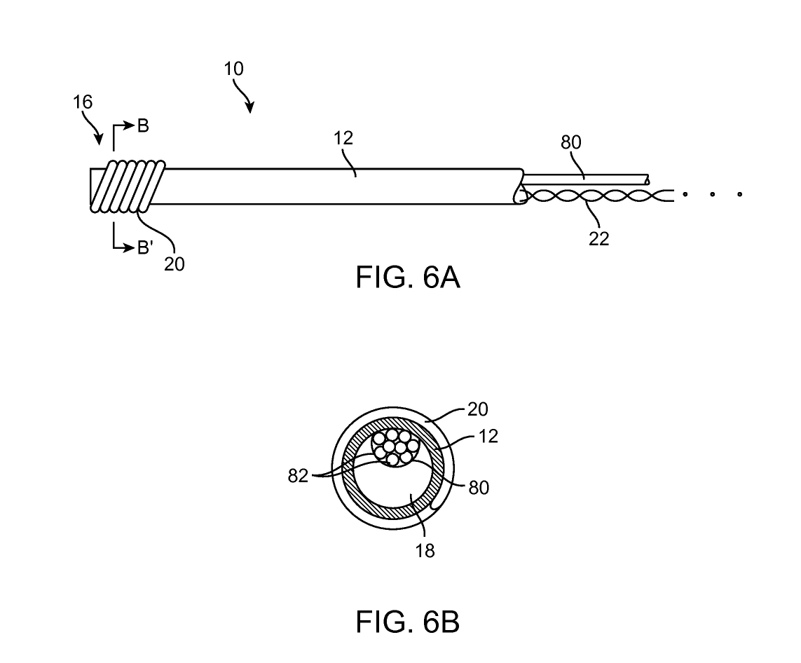

FIG. 6 illustrates an alternative embodiment of the magnetic imaging device 10. In this embodiment, a fiber optic bundle 80 containing a plurality of optical fibers 82 is contained within the lumen 18 of the elongate flexible member 12. The fiber optic bundle 80 provides for spectroscopy or viewing functionality to the magnetic imaging device 10. Certain of the optical fibers 82 may be coupled to a source of illumination (not shown) to illuminate the tissue. Other optical fibers 82 contained within the bundle 80 are configured to receive light and transmit the same toward the proximal end of the magnetic imaging device 10 which can then be used for imaging or spectroscopic purposes. While a single bundle 80 is illustrated in FIG. 6, it should be understood that multiple bundles 80 may be used. For example, one bundle 80 could contain the optical fibers 82 used for light transmission while another separate bundle 80 could contain the optical fibers 82 used for light receiving. As yet another alternative, the optical fibers 82 may not necessarily be contained within a discrete bundle 80.

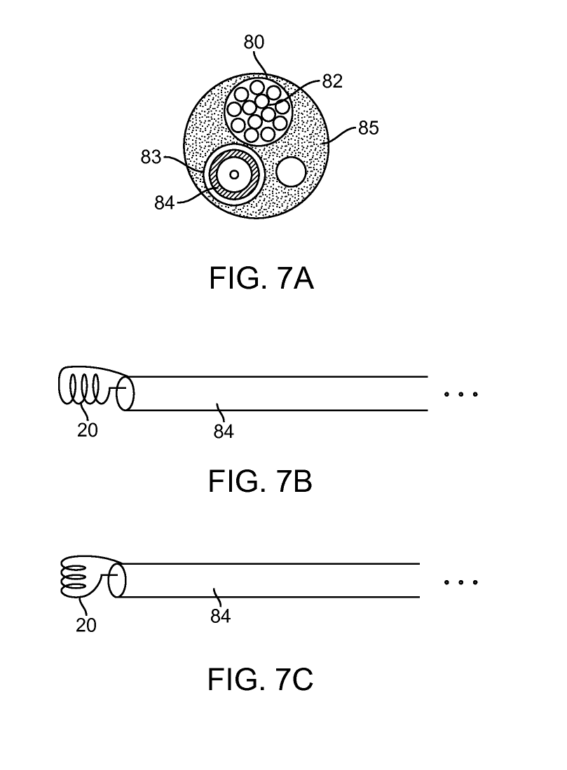

FIG. 7A illustrates an embodiment in which the solenoid coil 20 (illustrated in FIGS. 7B and 7C) can be deployed trough the working channel or lumen 83 of a visualization device 85 such as an endoscope. The endoscope 85 may include a fiber optic bundle 80 with a plurality of optical fibers 82 as illustrated in FIG. 7A. The optical fibers 82 may be used for light transmission/reception as is known in the art. In this embodiment, the open-lumen magnetic imaging device 10 as illustrated, for example, in FIG. 1A is no longer necessary. In this embodiment, a coaxial cable 84 is used alone, as depicted in FIGS. 7B and 7C, or in concert with an elongated flexible member 12 that is affixed or is otherwise connected to the solenoid coil 20. The solenoid coil 20 can be parallel to the long axis of the coaxial cable 84 as illustrated in FIG. 7B or, alternatively, the solenoid coil 20 can be perpendicular to the long axis of the coaxial cable 84 as illustrated in FIG. 7C. The twisted pair of leads 22 found in the prior embodiments is substituted for the coaxial leads contained in the coaxial cable 84. The coaxial leads of the coaxial cable 84 may be entirely encased in a protective sheath providing a moisture barrier and prevents contact of the device 10 with the tissue under examination. Electronic circuitry 52 for tuning/matching and decoupling the solenoid coil 20 can be integrated at the distal end 16, the proximal end 14, or a combination of the two.

The implantable solenoid coils 20 described herein pick-up more signal and less noise than conventional receive coils, providing small regions of enhanced SNR. While 3-T MRI typically provides 1 to 30 voxels per cubic millimeter, the MRI solenoid coils 20 can provide hundreds and even thousands of voxels in the same volume without degrading SNR.

While embodiments of the present invention have been shown and described, various modifications may be made without departing from the scope of embodiments of the present invention. Embodiments of the invention, therefore, should not be limited, except to the following claims, and their equivalents.

1. A magnetic resonance imaging device comprising:
an elongate flexible member having a proximal end, a distal end, and a lumen extending between the proximal end and the distal end;
a solenoid coil affixed to the distal end of the elongate flexible member, the solenoid coil having a plurality of wire turns, the solenoid coil connected to a twisted-pair of leads extending proximally along the length of the flexible member; and
a connector disposed at the proximal end of the elongate flexible member, the connector operatively coupled to the twisted-pair of leads.

2. The device of claim 1, wherein the connector comprises a SMA connector.

3. The device of claim 2, wherein the connector comprises a tuning capacitor and a matching inductor.

4. The device of claim 1, further comprising a stylet configured for insertion and retraction in the lumen of the elongate flexible member.

5. The device of claim 1, wherein the elongate flexible member comprises silicone tubing.

6. The device of claim 1, wherein the solenoid coil has a diameter within the range of about 200 μm to about 2 mm.

7. The device of claim 1, wherein the solenoid coil has at least three wire turns.

8. The device of claim 1, further comprising a tubular jacket extending along elongate flexible member, the twisted-pair of leads interposed between the elongate flexible member and the tubular jacket, and the solenoid coil.

9. The device of claim 8, further comprising a polydimethylsiloxane (PDMS) coating.

10. The device of claim 1, further comprising a duplexer operatively coupled to a signal generator and a receiver.

11. The device of claim 10, further comprising an attenuator interposed between the signal generator and the duplexer.

12. The device of claim 10, further comprising a preamplifier interposed between the receiver and the duplexer.

13. The device of claim 10, wherein the duplexer comprises a pair of anti-parallel Schottky diodes.

14. The device of claim 10, wherein the duplexers comprises a pair of PIN diodes.

15. The device of claim 1, wherein the elongate flexible member further comprises a plurality of optical fibers extending from a proximal end to a distal end, the plurality of optical fibers comprising at least one light emitting fiber and at least one light receiving fiber.

16. A magnetic resonance imaging device comprising:
a coaxial cable having a proximal end, a distal end;
a solenoid coil affixed to the distal end of the coaxial cable, the solenoid coil having a plurality of wire turns, the solenoid coil connected to conductors extending proximally along the length of the coaxial cable; and
a connector disposed at the proximal end of the coaxial cable, the connector operatively coupled to the conductors of the coaxial cable.

17. The device of claim 16, further comprising an endoscope having a working channel or lumen therein, the magnetic resonance imaging device dimensioned for slideable movement within the working channel.

18. A method of using the device of claims 1 comprising:
placing a subject within a static magnetic field; and
inserting the elongate flexible member or coaxial cable into a tissue region of interest.

19. The method of claim 18, wherein the solenoid coil is generally perpendicular to the static magnetic field.

20. The method of claim 18, further comprising transmitting a signal to the tissue region of interest via the solenoid coil.

21. The method of claim 18, further comprising receiving a signal from the tissue region of interest via the solenoid coil.

22. The method of claim 18, further comprising coupling the connector to a duplexer operatively connected to a transmitter and receiver and operating the solenoid coil as a transceiver.

23. The method of claim 18, further comprising imaging the tissue region of interest via one or more optical fibers extending from a proximal end to a distal end of the elongate flexible member.

24. A method of making a magnetic resonance imaging coil comprising:
wrapping an insulated conductor around a tubular elongate member for a plurality of turns to form a solenoid coil;
forming a twisted-pair of leads from a portion of the insulated conductor; and
securing the twisted-pair of leads relative to the tubular elongate member.

25. The method of claim 24, wherein the insulated conductor is wrapped around a tubular elongate member containing a removable stylet.

26. The method of claim 25, further comprising removing the stylet.

27. The method of claim 24, wherein the twisted-pair of leads is secured relative to the tubular elongate member with an outer tubular jacket.

28. The method of claim 27, further comprising dipping the solenoid coil and a distal portion of the outer tubular jacket into polydimethylsiloxane (PDMS).
